(19) United States
(12) Patent Application Publication
(10) Pub. No.: US 2014/0070314 A1
(43) Pub. Date: Mar. 13, 2014

(54) SEMICONDUCTOR DEVICE AND SEMICONDUCTOR INTEGRATED CIRCUIT DEVICE USING THE SAME

(71) Applicant: Hitachi, Ltd., Tokyo (JP)

(72) Inventors: Shinji Shirakawa, Tokyo (JP); Junichi Sakano, Tokyo (JP)

(73) Assignee: Hitachi, Ltd., Tokyo (JP)

(21) Appl. No.: 13/964,223

(22) Filed: Aug. 12, 2013

(30) Foreign Application Priority Data
Sep. 11, 2012 (JP) 2012-199611

(51) Int. Cl. H01L 27/092

(52) U.S. Cl. CPC H01L 27/0922
USPC 257/338

(57) ABSTRACT

There is provided an MOSFET having a large current density, which can be mixed with a logic circuit, and is used in a circuit that conducts the operation of applying a negative voltage to a drain electrode. An electrode surrounded by an insulating film is formed, at an intermediate position of a gate electrode and a drain of the MOSFET formed on an SOI substrate having a drain electrode applied with a negative voltage, and the electrode is connected to the ground to prevent a withstand voltage from being lowered which is caused by an increase in impurity concentration of a drift region. A drift resistance is lowered to improve the current density.

### BACKGROUND OF THE INVENTION

1. Field of the Invention

The present invention relates a semiconductor device using an insulated gate called “MOSFET (metal oxide semiconductor field effect transistor)” or “MISFET (metal insulator semiconductor field effect transistor), and semiconductor integrated circuit device using the semiconductor device.

2. Background Art

In recent years, semiconductor integrated circuit. devices large in logic scale have been increasingly developed with a functional aggregation or high functionality. In a field of an analog-digital mixed integrated circuit, an semiconductor integrated circuit device in which a middle or high withstand voltage element of 20V to 600V class are combined with a low is circuit having a CMOS (complementary MOSFET) configuration has been developed for on-vehicle, industrial, and medicinal purpose. The analog-digital mixed integrated circuit of this type has been designed and. developed to customize a function to be realized by a product, and improvements in the required performance of the semiconductor integrated circuit device (hereinafter referred to as “IC”) and the performance of a semiconductor element used in the semiconductor integrated circuit device have also been demanded.

As disclosed in JP-A-11-145462, an SOI (silicon on insulator) substrate having an oxide film interposed between a silicon support substrate and a silicon layer forming a semiconductor circuit is suitable for the IC in which a plurality of high withstand voltage semiconductor elements, and a semiconductor element of a logic circuit section configuring a driver circuit are integrated on one semiconductor substrate, and used for a high withstand voltage power IC.

The analog-digital mixed integrated circuit is exemplified by a medical ultrasound pulser IC that outputs a positive and negative symmetrical voltage waveform illustrated in FIG. 3 from a plurality of channels to an ultrasound vibrator, emits an ultrasound wave from the ultrasound vibrator to an inspection target, and receives a voltage signal of the vibrator that receives an echo from the inspection target.

As the circuit that outputs the positive and negative symmetrical voltage waveform, an output stage circuit illustrated in FIG. 2 is used. The circuit of FIG. 2 is a bridge circuit having a p-type MOSFET as a highside (upper arm), and an n-type MOSFET as a lowside (lower arm). A source electrode of the p-type MOSFET on the highside is connected with a power supply of a positive potential, and a source electrode of the n-type MOSFET on the lowside is connected with a power supply of a negative potential. When it is assumed that a positive output voltage of a power supply 26 is +Vp, and a negative output voltage of a power supply 27 is −Vm, Vp and Vm range from 50 to 150V. When the n-type MOSFET on the lowside is off, and a gate voltage is applied to a gate electrode of the p-type MOSFET on the highside to turn on the p-type MOSFET, +Vp is output to an output terminal connected to a drain electrode of the p-type MOSFET. On the other hand, when the p-type MOSFET on the highside is off, and a gate voltage is applied to a gate electrode of the n-type MOSFET on the lowside to turn on the n-type MOSFET on the lowside, −Vm is output to an output terminal connected to a drain electrode of the n-type MOSFET.

In manufacturing the integrated circuit, a semiconductor substrate in which an n-type silicon layer is formed on an inexpensive p-type support substrate is frequently used. However, when the bridge circuit on the output stage in FIG. 2 is fabricated on the semiconductor substrate, a current flows between the p-type support substrate connected to the ground for the purpose of preventing a parasitic element operation, and the source of the n-type MOSFET on the lowside. For that reason, in fabrication of the bridge circuit, in order to break down a current path between the ground and the n-type MOSFET source, the 301 (silicon on insulator) substrate in which an insulating film formed of an oxide film is interposed between the support substrate and the silicon layer forming the semiconductor circuit is suitable.

Also, the output stage circuit of FIG. 2 occupies a wide area of the IC, and particularly the p-type MOSFET on. the highside occupies the wide area. Because a current flows in the p-type MOSFET with holes as carriers, the p-type MOSFET is low in current density per unit area as compared with the n-type MOSFET which uses electrons as carriers. Therefore, in order to realize the positive and negative symmetrical output waveform, an area of the p-type MOSFET must be increased according to the current density.

In order to downsize the chip area and reduce the costs of the analog-digital mixed integrated circuit that conducts a middle or high voltage operation, such as the medical ultrasound puller IC, there is a need to improve the output performance of the p-type MOSFET used in the bridge circuit of FIG. In the p-type MOSFET of a middle or high withstand voltage used in the bridge circuit of FIG. 2, a p-type drift region extending from a drain region toward under the gate electrode is provided. Therefore, as a method of improving the output performance of the p-type MOSFET, there is a method of increasing a p-type impurity concentration of the p-type drift region, and decreasing an electric resistance of the drift region. However, when the p-type impurity concentration of the drift region becomes higher, the p-type region of the drain side does not become depleted, and a region in which a voltage difference is generated between the source and the drain is shortened. For that reason, an electric intensity leading to an avalanche is reached at a lower voltage as the p-type impurity concentration of the drift region is higher. That is, the impurity concentration of the drift region has a trade-off relationship with the withstand voltage and the output current density, and the p-type impurity concentration of the drift region cannot be increased in a unilateral way.

Also, in the output stage circuit of FIG. 2, the n-type MOSFET and the p-type MOSFET alternately turn on/off, to thereby apply a negative high voltage to the source of the n-type MOSFET, and a positive high voltage to the drain of the n-type MOSFET on the lowside. Therefore, in the improvement in the withstand voltage, the same as that in the p-type MOSFET is applied to the n-type MOSFET on the lowside.

### SUMMARY OF THE INVENTION

Under the above circumstances, an object of the present invention is to provide a p-type (n-type) MOSFET that facilitates the depletion of a drift region on a drain side of the p-type (n-type) MOSFET, and improves a withstand voltage and an output current density, and also to provide a semiconductor integrated circuit device using the above p-type (n-type) MOSFET.

In order to solve the above problem, according to the present invention, there is provided a semiconductor device in which a p-type (n-type) MOSFET is formed on an SOI substrate, a negative (positive) high voltage is applied to a drain of the MOSFET, a positive (negative) high voltage is applied to a source thereof, an addition electrode is disposed on an insulating film thicker than a gate insulating film located between a source region and a drain region thereof, and the addition electrode is connected to a support substrate potential of the SOI substrate, a peripheral island potential (ground potential), or a potential regarded as the ground (supply voltage of a logic circuit section which is equal to or lower than, for example, 5V).

Also, the semiconductor integrated circuit device according to the present invention includes a circuit that uses, as a circuit element, the p-type (n-type) MOSFET that is formed on the SOI substrate, and connects the addition electrode disposed on the insulating film thicker than the gate insulating film located between the source and the drain to the ground potential, in which a negative (positive) high voltage is applied to the drain of the p-type (n-type) MOSFET, and a positive (negative) high voltage is applied to the source thereof.

The semiconductor device and the semiconductor integrated circuit device using the same according to the present invention can realize the higher concentration and higher withstand voltage of the drift region that extends from the drain region toward under the gate electrode by the above solution to the problem.

For example in a circuit of FIG. 2, when the p-type MOSFET of the highside is off, and the n-type MOSFET of the lowside is on, a positive supply voltage is applied. to the source electrode of the p-type MOSFET, and a negative supply voltage is applied to the drain electrode thereof. The addition electrode disposed on the insulating film at an intermediate position of the gate electrode and the drain electrode of the p-type MOSFET, and connected to the ground, depletes the p-type drift region due to a potential difference from the source electrode, and improves a tradeoff relationship of the withstand voltage and the output current density.

### BRIEF DESCRIPTION OF THE DRAWINGS

FIG. 1 is a cross-sectional structural view illustrating a semiconductor device according to a first embodiment of the present invention;

FIG. 2 is a diagram illustrating an example of a circuit within a semiconductor integrated circuit device according to the present invention;

FIG. 3 is a diagram illustrating an output voltage waveform of the circuit in FIG. 2;

FIG. 4 is a potential distribution diagram in a withstand voltage calculation of a p-type MOSFET without applying the present invention;

FIG. 5 is a potential distribution diagram in a withstand voltage calculation of a p-type MOSFET according to the present invention;

FIG. 6 is a cross-sectional structural view of a semiconductor device in a related art;

FIG. 7 is a graph illustrating withstand voltage calculation results of the p-type MOSFETs having the cross-sectional structures in FIGS, 4 and 5;

FIG. 8 is a cross-sectional structural view illustrating a semiconductor device according to a second embodiment of the present invention; and

FIG. 9 is a circuit block diagram illustrating an example of a digital-analog mixed integrated circuit using the semiconductor device according to the embodiment of the present invention.

### DETAILED DESCRIPTION OF THE PREFERRED EMBODIMENTS

Embodiments of the present invention will be described hereinafter with reference to the accompanying drawings. The following embodiments exemplify specific examples of the contents of the present invention, and the present invention is not limited to the following embodiments, but modifications and applications can be variously made by an ordinary skilled person without departing from the scope of the technical concept disclosed in the present specification. Also, in all the drawings for describing the embodiments, identical members are in principle denoted by like reference numerals, thereby omitting detailed description thereof.

In the following embodiments, in an integrated circuit formed on an SOI substrate, having a circuit in which a positive potential is applied to a source of a p-type MOSFET, and a negative potential is applied to a drain thereof to provide an operation period during which an off state of the p-type MOSFET is held, an addition electrode connected to the ground is arranged between a source region and a drain region of the p-type MOSFET. In addition, a support substrate of the SOI substrate is connected to the ground. With the above configuration, a withstand voltage can be improved, the impurity concentration of a p-type drift region of the p-type MOSFET can be set to a maximum concentration that can achieve a withstand voltage target, and the output current density can be improved.

### First Embodiment

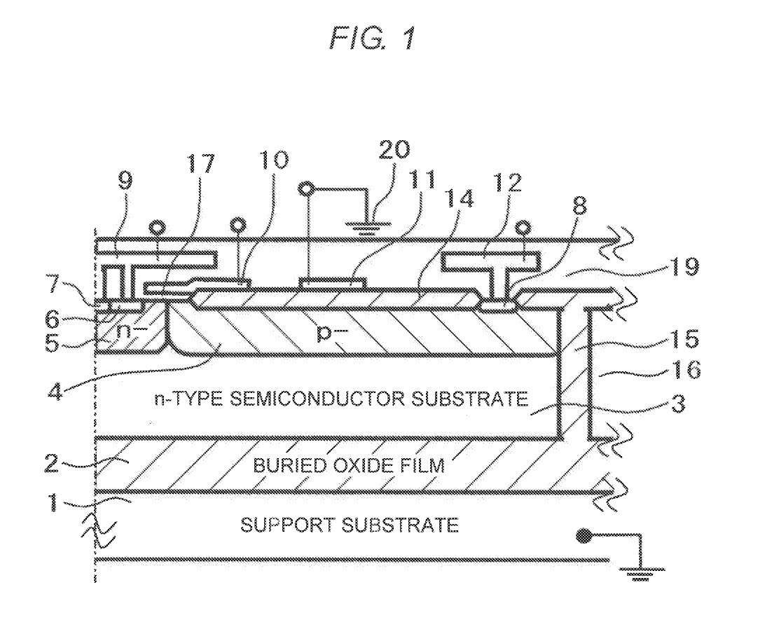

Hereinafter, a first embodiment of the present invention will be described in detail with reference to the attached drawings. FIG. 1 is a partially cross-sectional structural view illustrating a horizontal p-type MOSFET according to the first embodiment of the present invention. Referring to FIG. 1, the horizontal p-type MOSFET according to the present invention is structured bilaterally symmetrically, and a right half of the structure is illustrated, and a left half thereof is omitted from the figure.

Referring to FIG. 1, a support substrate 1 formed of a p-type or an n-type silicon substrate, and an n-type semiconductor substrate 3 are isolated from each other by a buried oxide film 2. Also, an insulting film 14 thicker than a gate insulating film 17 and is formed of an oxide film or the like is selectively formed on a surface layer of the n-type semiconductor substrate 3. The insulting film 14 formed of the oxide film or the like corresponds to LOCOS (local oxidation on silicon) or STI (shallow trench isolation) . Referring to FIG. 1, an n-type base region 5 is selectively formed on the surface layer of the n-type semiconductor substrate 3, and a p-type source region 6 and an n-type contact region 7 are partially formed on a surface of the n-type base region 5. A source electrode 9 is connected to the p-type source region 6 and the n-type contact region 7. The p-type source region 6 and the n-type base region 5 may be arranged adjacent to each other.

Also, a p-type drift region 4 is selectively formed on the surface layer of the n-type semiconductor substrate 3. A p-type drain region 8 is partially formed on a surface layer of the p-type drift region 4, A drain electrode 12 is connected to the p-type drain region 8. The p-type drain region 8 and the p-type drift region 4 may be arranged adjacent to each other.

A gate electrode 10 made of Poly-Si or the like is selectively formed on the gate insulating film 17 formed of the thin oxide film or the like, which is formed on the surfaces of the n-type base region 5 and the p-type drift region 4, and the insulting film 14 thicker than the gate insulating film 17. In a silicon region under the gate electrode 10 are arranged the p-type source region 6, the n-type base region 5, the p-type drift region 4, and the p-type drain region 8 in the state order from a source side thereof An insulating film 19 functions as an interlayer insulating film or a protective film formed of an oxide film or a nitride film.

An addition electrode 11 connected to a ground 20 is formed between the gate electrode 10 and the p-type drain region 8, and on the thick insulting film 14 formed of the oxide film or the like. In FIG. 1, the support substrate 1 and the addition electrode 11 are connected to the ground. The source electrode 9, the drain electrode 12, and the gate electrode 10 are connected to respective lines of an integrated circuit,.

An oxidation separation region 15 may be disposed in addition to a main element structure of the present invention. The oxidation separation region 15 is designed to electrically separate the respective semiconductor devices that cannot share the potential of the n-type semiconductor substrate 3 among the elements formed on the surface of the n-type semiconductor substrate 3 from each other. An n-type semiconductor substrate 16 in an adjacent semiconductor element region is an n-type semiconductor substrate on another element side which cannot share the potential with the n-type semiconductor substrate 3 of the p-type MOSFET in FIG. 1.

FIG. 6 illustrates a p-type MOSFET having no addition electrode connected to the ground of the present invention. Differences in the p-type MOSFET between FIGS. 6 and 1 reside in that the addition electrode 11 connected to the ground is provided in FIG. 1, and the impurity concentration of the p-type drift region 4 in FIG. 1 is higher than that of the p-type drift region 4 in FIG. 6. For example, the impurity concentration of the p-type drift region 4 in FIG. 1 of the present invention can be increased to about 1.3 to 1.5 times of the impurity concentration of the p-type drift region 4 in FIG. 6.

Subsequently, a method of forming the addition electrode 11 will be described. The addition electrode 11 can be formed in a process of forming the gate electrode 10. For example, after the gate insulating film 17 has been formed on the surface layer of the n-type semiconductor substrate 3, a poly-Si electrode layer is formed on an overall surface of the substrate, and a protective oxide film of the gate electrode is formed on the poly-Si electrode layer. Thereafter, the protective oxide film of the gate electrode, and the poly-Si electrode layer are selectively etched so as to remain the gate electrode 10 and the addition electrode 11 with the use of a mask. With this processing, the addition electrode 11 connected to the ground can be formed.

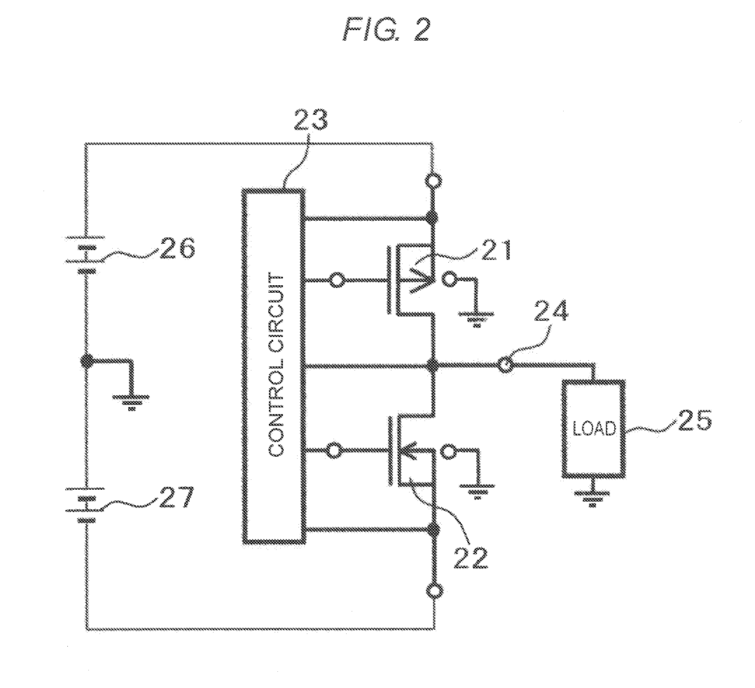

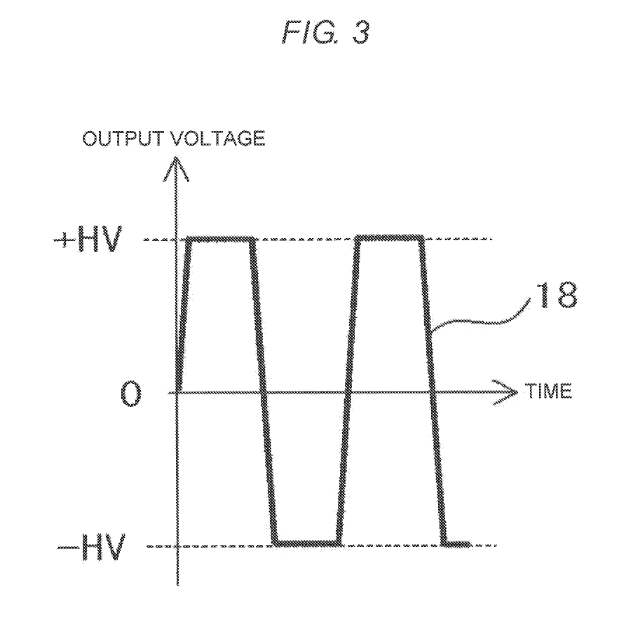

Subsequently, a principle of the present invention will be described. The horizontal p-type MOSFET according to the present invention is used in, for example, a circuit that outputs a positive and negative voltage 18 illustrated in FIG. 3. The circuit that outputs the positive and negative voltage 18 is exemplified by a bridge circuit illustrated in FIG. 2. FIG. 2 illustrates the bridge circuit using a p-type MOSFET on the highside, and an n-type MOSFET on the lowside. In the bridge circuit that connects a power supply 26 and a power supply 27, a control circuit 23 allows the respective MOSFETs of the highside and the lowside to alternately turn on/off, thereby outputting, from a terminal 24, a voltage waveform changed from a positive potential to a negative potential, and from the negative potential to the positive potential illustrated in FIG. 3.

Referring to FIG. 2, when a p-type MOSFET 21 of the highside is off, and an n-type MOSFET 22 of the lowside is on, a positive potential of the power supply 26 is applied to a source of the p-type MOSFET 21, and substantially a negative potential of the power supply 27 is applied to a drain of the p-type MOSFET 21. In addition, in the applied circuit of the present invention, the negative potential is applied to a source of the n-type MOSFET 22, and the support substrate 1 is connected to the ground for the purpose of stabilizing the operation of the respective semiconductor devices within the IC. For that reason, it is essential to isolate the n-type semiconductor substrate 3 forming the semiconductor element from the support substrate 1 by the buried oxide film 2 illustrated in FIG. 1. As a result, the p-type MOSFET 21 can be kept in an off state when the source of the p-type MOSFET 21 is the positive potential, the drain thereof is the negative potential, and the support substrate 1 is the ground potential.

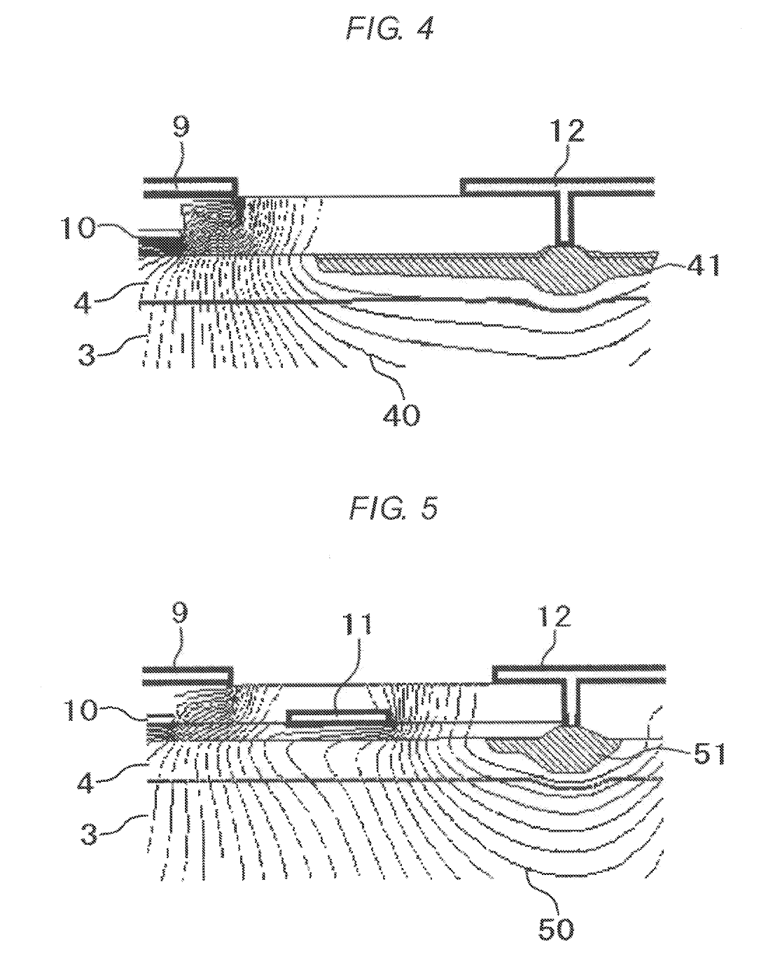

FIG. 4 illustrates a potential distribution (calculation results) 40 between the gate electrode and the drain electrode when the impurity concentration of the p-type drift region 4 is made relatively higher than that of the related art p-type MOSFET, and a potential difference between the source and the drain immediately before an avalanche phenomenon is generated is applied therebetween, in the p-type MOSFET structure without the addition electrode illustrated in FIG. 6. In the calculation, the positive potential is applied to the source, the negative potential is applied to the drain, and no potential is applied to the support substrate.

In potential boundary conditions of FIG. 4, as compared with a case in which the power supply 27 in FIG. 2 is not provided, and the source of the n-type MOSFET 22 becomes the ground potential, an electric field applied to the p-type drift region 4 from the n-type semiconductor substrate 3 becomes relatively weakened from the source toward the drain. For that reason, as compared with the case in which the power supply 27 is not provided, and the source of the n-type MOSFET 22 becomes the ground potential, it is difficult to deplete the p-type drift region 4. Referring to FIG. 4, a hatched region 41 is not depleted. The region 41 not depleted has substantially the same potential as that of the drain, and that the region 41 is large means that a region in which a potential drops due to depletion is narrow, that is, a potential gradient is large. Therefore, because the avalanche phenomenon is generated at a low voltage, the withstand voltage becomes low.

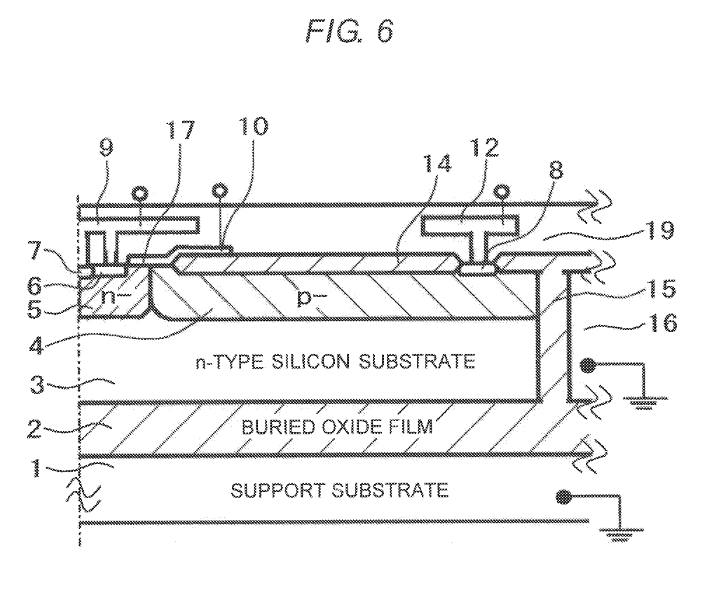

FIG. 5 illustrates a potential distribution (calculation results) 50 between the gate electrode 10 and the drain electrode 12 when a potential difference immediately before the avalanche phenomenon is generated is applied between the source and the drain of the p-type MOSFET having the p-type drift region 4 with the same relatively high impurity concentration as that in FIG. 4, and having the addition electrode 11 connected to the ground. In the calculation of FIG. 5, the positive potential is applied to the source, the negative potential is applied to the drain, and no potential is applied to the support substrate, as in FIG. 4, Referring to FIG. 5, a hatched region 51 is not depleted. The region 51 not depleted. has substantially the same potential as that of the drain, and that the region 53 is small means that a region in which a potential drops due to depletion is broad, that is, the potential gradient is small. Therefore, the voltage at which the avalanche phenomenon is generated can be increased as compared with that in the structure of FIG. 4.

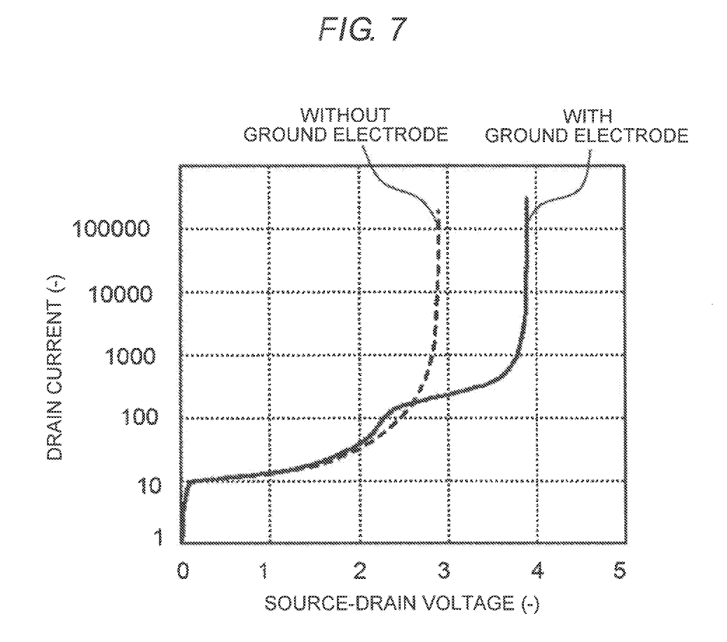

FIG. 7 illustrates calculation results of a drain current to a source-drain voltage in the structures of FIGS. 4 and 5. A source-drain voltage at which the drain current rapidly increases is an avalanche voltage, that is, the withstand voltage. From the results of FIG. 7, it is found that the p-type MOSFET having the addition electrode 11 connected to the ground has the withstand voltage of about 1.3 times as large as that. when the addition electrode 11 is not provided. In this way, in the present invention, the ground potential requiring no new power supply is applied to the addition electrode 11, thereby increasing the region in which the p-type drift region 4 is depleted, and increasing the withstand voltage.

In this example, because the region that is depleted by the addition electrode 11 connected to the ground is determined according to a width of the addition electrode 11 in a direction from the source toward the drain, some width is necessary. Also, when the addition electrode 11 comes closer to the drain side, the potential gradient therebetween is determined according to the ground and the drain potential. Therefore, a distance at which the avalanche is not generated before the target withstand voltage is obtained is required. Likewise, when the ground electrode comes closer to the gate electrode side, the potential gradient therebetween is determined according to the ground and the gate potential. As a result, the distance at which the avalanche is not generated before the target withstand voltage is obtained is required.

Hence, a width and a position of the ground electrode are determined according to a balance of the voltages of the power supply 26 and the power supply 27 in FIG. 2. For example, when the positive power supply 26 and the negative power supply 27 each have a power supply that outputs a voltage of the same magnitude, the addition electrode 11 connected to the ground is arranged on the basis of an intermediate point between the gate electrode end and the drain electrode, and the ground electrode width is adjusted so that the target withstand voltage is achieved with the highest impurity concentration of the p-type drift region 4.

As described above, with the configuration of the p-type MOSFET according to the present invention, the occupied area of the p-type MOSFET occupying a large area in the analog-digital mixed integrated circuit such as the medical ultrasound pulser IC chip can be reduced. As a result, the IC chip can be downsized. For example, in the medical ultrasound pulser IC chip, the IC chip can be downsized, to thereby increase the output current density.

### Second Embodiment

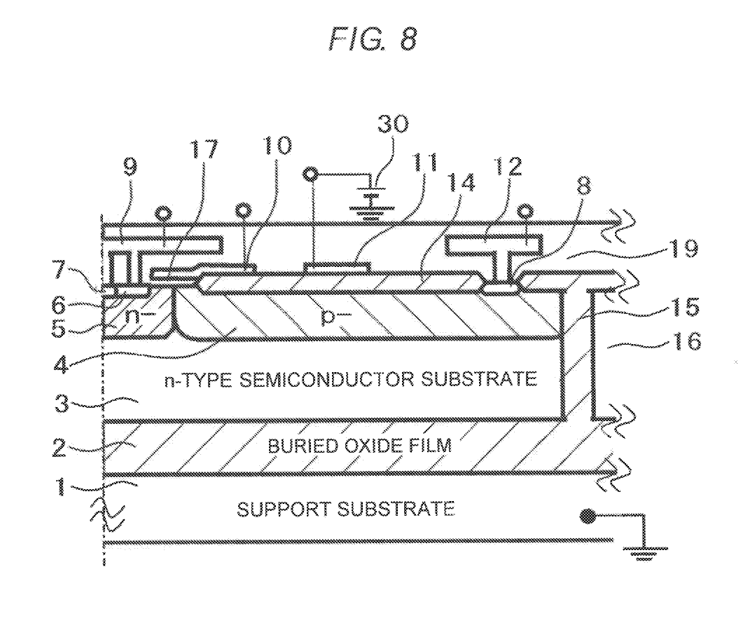

Subsequently, a second embodiment of the present invention will be described. FIG. 8 is a partially cross-sectional structural view illustrating a horizontal p-type MOSFET according to the second embodiment of the present invention. A difference from FIG. 1 of the first embodiment resides in that a voltage across a power supply 30 for a logic circuit used in the control circuit is applied to the addition electrode. The power supply for the logic circuit is about 5V or 3.3V with respect to the ground, and as compared with the power supply 26 (for example, +50 to 150 V) and the power supply 27 (for example, −50 to 150 V) in FIG. 2, the voltage of −5V to +5V is regarded as substantially the same potential as the ground potential. That is, the power potential of 5V or 3.3V used as the supply voltage for the logic circuit is regarded as substantially the same potential as the ground potential. Therefore, when the voltage of, for example, 5V or 3.3V is applied to the addition electrode, the above problem can be solved by the same principle as that in the first embodiment.

### Third Embodiment

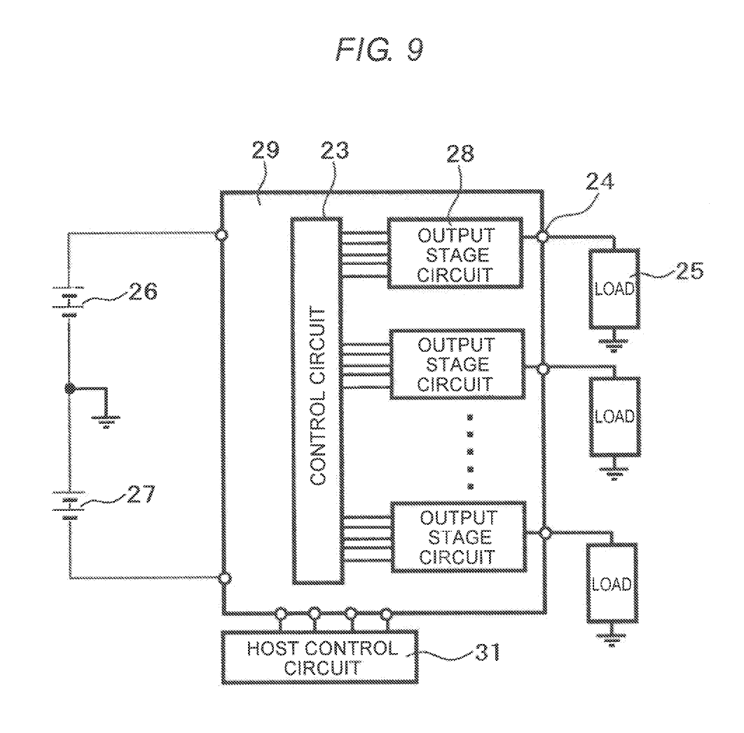

Subsequently, a third embodiment of the present invention will be described. FIG. 9 illustrates an example of a digital-analog mixed integrated circuit 29 applying the p-type MOSFET according to the present invention. Each of output stage circuits 28 of the digital-analog mixed integrated circuit 29 is the bridge circuit using the p-type MOSFET 21 and the n-type MOSFET 22 illustrated in FIG. 2. Each of the output stage circuits 28 is subjected to on/off control by the control circuit 23 to output the voltage waveform of FIG. 3. Also, the control circuit 23 controls the on/off operation of the respective output stage circuits 28 according to a control signal from the a host control circuit 31, and also transmits a result obtained by measuring a voltage across the terminal 24 to the host control circuit 31. The p-type MOSFET of the present invention is applied to the digital-analog mixed integrated circuit 29, thereby being capable of downsizing the output stage circuits 28, that is, downsizing the chip area of the digital-analog mixed integrated circuit 29. With the downsized chip area, the number of chips that can be obtained from each semiconductor wafer can be increased, and the costs can be resultantly reduced.

In the above description of the embodiments, the improvement in the withstand voltage and the output current density in the p-type MOSFET has been described in detail.

Similarly, in the n-type MOSFET, the effect of the improvement in the withstand voltage and the output current density can be expected. In particular, in the output stage circuit of FIG. 2, the n-type MOSFET and the p-type MOSFET alternately turn on/off as a result of which the negative high voltage is applied to the source of the n-type MOSFET, and the positive high voltage is applied to the drain thereof. Therefore, in order to improve the withstand voltage of the n-type MOSFET, the same advantages can be expected with the provision of the addition electrode 11 connected to the ground in FIG. 1.

The present invention is useful in the insulating gate structure transistor of the middle and high withstand voltage formed on the SOI substrate, and the semiconductor integrated circuit device using the same. In particular, the present invention is high in the applicability, as the analog-digital mixed integrated circuit such as the medical ultrasound pulser IC.

What is claimed is:

1. A semiconductor device, comprising:
a semiconductor substrate having a structure in which a buried insulating film is formed between a support substrate and a first conductivity type semiconductor layer;
a first conductivity type base region that is selectively formed on a surface side of the first conductivity type semiconductor layer;
a second conductivity type source region that is formed within or adjacent to the first conductivity type base region;
a second conductivity type drift region that is selectively formed on the surface side of the first conductivity type semiconductor layer, and formed adjacent to the first conductivity type base region;
a second conductivity type drain region that is selectively formed on the surface side of the first conductivity type semiconductor layer, and formed within or adjacent to the second conductivity type drift region;
a gate insulating film that is formed on the second conductivity type source region and the first conductivity type base region;
an insulating film that is formed on the second conductivity type drift region, and thicker than the gate insulating film;
a gate electrode that is formed on the gate insulating film; and
an addition electrode that is disposed on the insulating film thicker than the gate insulating film, and is connected to the same potential as that of the support substrate,
wherein, in a circuit using the semiconductor device as a circuit element, a negative potential is applied to one of the second conductivity type drain region and the second conductivity type source region with respect to the potential of the support substrate.

2. The semiconductor device according to claim 1,
wherein the semiconductor device is a p-type MOSFET, and when the p-type MOSFET turns off in the circuit, a positive voltage is applied to a source of the p-type MOSFET, and a negative voltage is applied to a drain of the p-type MOSFET.

3. A semiconductor integrated circuit device comprising the semiconductor device according to claim 1.

4. The semiconductor integrated circuit device according to claim 3, further comprising:
an output stage circuit in which a drain of a p-type MOSFET on the highside, and a drain of an n-type MOSFET on the lowside are connected to each other, and the p-type MOSFET and the n-type MOSFET are connected in series with each other; and
a logic circuit that controls the output stage circuit.

5. The semiconductor integrated circuit device according to claim 4,
wherein a power supply of a positive potential is connected to a source of the p-type MOSFET on the highside, and a power supply of a negative potential is connected to a source of the n-type MOSFET on the low side.

6. A semiconductor device, comprising;
a semiconductor substrate having a structure in which. a buried insulating film is formed between a support substrate and a first conductivity type semiconductor layer;
a first conductivity type base region that is selectively formed on a surface side of the first conductivity type semiconductor laver;
a second conductivity type source region that is formed within or adjacent to the first conductivity type base region;
a second conductivity type drift region that is selectively formed on the surface side of the first conductivity type semiconductor layer, and formed adjacent. to the first conductivity type base region;
a second conductivity type drain region that is selectively formed on the surface side of the first conductivity type semiconductor layer, and formed within or adjacent to the second conductivity type drift region;
a gate insulating film that is formed on the second conductivity type source region and the first conductivity type base region;
an insulating film that is formed on the second conductivity type drift region, and thicker than the gate insulating film;
a gate electrode that is formed on the gate insulating film; and
an addition electrode that is disposed on the insulating film thicker than the gate insulating film,
wherein the first conductivity type semiconductor layer is sectioned into a plurality of island regions surrounded by the buried insulating film and insulation separation regions that section the first conductivity type semiconductor layer into island shapes, and the semiconductor device is formed in a first island region of the plurality of island regions,
wherein a semiconductor element of a logic circuit that controls the semiconductor device is formed in a second island region of the plurality of island regions, and the addition electrode is connected to the same potential as a potential of the second island region, and
wherein, in a circuit using the semiconductor device as a circuit element, a negative potential is applied to one of the second conductivity type drain region and the second conductivity type source region with respect to a potential of the support substrate.

7. The semiconductor device according to claim 6,
wherein the semiconductor device is a p-type MOSFET, and when the p-type MOSFET turns off in the circuit, a positive voltage is applied to a source of the p-type MOSFET, and a negative voltage is applied to a drain of the p-type MOSFET.

8. A semiconductor integrated circuit device comprising the semiconductor device according to claim 6.

9. The semiconductor integrated circuit device according to claim 8, further comprising:
an output stage circuit in which a drain of a p-type MOSFET on the highside, and a drain of an n-type MOSFET on the lowside are connected to each other, and the p-type MOSFET and the n-type MOSFET are connected in series with each other; and
a logic circuit that controls the output stage circuit,

10. The semiconductor integrated circuit device according to claim 9,
wherein a power supply of a positive potential is connected to a source of the p-type MOSFET on the highside, and a power supply of a negative potential is connected to a source of the n-type MOSFET on the low side.

11. A semiconductor device, comprising:
a semiconductor substrate having a structure in which a buried insulating film is formed between a support substrate and a first conductivity type semiconductor layer;
a first conductivity type base region that is selectively formed on a surface side of the first conductivity type semiconductor layer;
a second conductivity type source region that is formed within or adjacent to the first conductivity type base region;
a second conductivity type drift region that is selectively formed on the surface side of the first conductivity type semiconductor layer, and formed adjacent to the first conductivity type base region;
a second conductivity type drain region that is selectively formed on the surface side of the first conductivity type semiconductor layer, and formed within or adjacent to the second conductivity type drift region;
a gate insulating film that is formed on the second conductivity type source region and the first conductivity type base region;
an insulating film that is formed on the second conductivity type drift region, and thicker than the gate insulating film;
a gate electrode that is formed on the gate insulating film; and
an addition electrode that is disposed on the insulating film thicker than the gate insulating film, and is applied with a potential equal to or higher than −5V, and equal to or lower than 5V,
wherein, in a circuit using the semiconductor device as a circuit element, a negative potential is applied to one of the second conductivity type drain region and the second conductivity type source region with respect to a potential of the support substrate.

12. The semiconductor device according to claim 11,
wherein the semiconductor device is a p-type MOSFET, and when the p-type MOSFET turns off in the circuit, a positive voltage is applied to a source of the p-type MOSFET, and a negative voltage is applied to a drain of the p-type MOSFET.

13. The semiconductor device according to claim 11,
wherein the potential applied to the addition electrode is a power potential of a logic circuit that controls the semiconductor device.

14. The semiconductor device according to claim 11,
wherein the potential applied to the addition electrode is a ground potential.

15. The semiconductor device according to claim 14,
wherein the potential applied to the addition electrode is a ground potential connected to the support substrate.

16. The semiconductor device according to claim 11,
wherein the first conductivity type semiconductor layer is sectioned into a plurality of island regions surrounded by the buried insulating film and insulation separation regions that section the first conductivity type semiconductor layer into island shapes,
wherein the semiconductor device is formed in at least one island region of the plurality of island regions,
wherein a semiconductor element of a logic circuit that controls the semiconductor device is formed in at least another island region of the plurality of island regions, and
wherein a ground potential applied to the addition electrode is a ground potential connected with the island region in which the semiconductor element of the logic circuit is formed.

17. The semiconductor device according to claim 13,
wherein the semiconductor device is a p-type MOSFET, and when the p-type MOSFET turns off in the circuit, a positive voltage is applied to a source of the p-type MOSFET, and a negative voltage is applied to a drain of the p-type MOSFET.

18. A semiconductor integrated circuit device comprising the semiconductor device according to claim 11.

19. The semiconductor integrated circuit device according to claim 18, further comprising:
an output stage circuit in which a drain of a p-type MOSFET on the highside, and a drain of an n-type MOSFET on the lowside are connected to each other, and the p-type MOSFET and the n-type MOSFET are connected in series with each other; and
a logic circuit that controls the output stage circuit

20. The semiconductor integrated circuit device according to claim 19,
wherein a power supply of a positive potential is connected to a source of the p-type MOSFET on the highside, and a power supply of a negative potential is connected to a source of the n-type MOSFET on the low side.
